(19) United States
(12) Patent Application Publication
(10) Pub. No.: US 2024/0250209 A1
(43) Pub. Date: Jul. 25, 2024

(54) NITRIDE SEMICONDUCTOR LIGHT-EMITTING ELEMENT

(71) Applicant: Nuvoton Technology Corporation Japan, Kyoto (JP)

(72) Inventors: Yasutoshi KAWAGUCHI, Toyama (JP); Shinji YOSHIDA, Shiga (JP); Takahiro OKAGUCHI, Toyama (JP); Shuichi NAKAZAWA, Toyama (JP); Shigeo HAYASHI, Kyoto (JP); Masayuki HATA, Osaka (JP)

(21) Appl. No.: 18/583,573

(22) Filed: Feb. 21, 2024

Related U.S. Application Data
(63) Continuation-in-part of application No. PCT/JP2022/029988, filed on Aug. 4, 2022.

(30) Foreign Application Priority Data
Aug. 26, 2021 (JP) 2021-138405

(51) Int. Cl. H01L 33/14; H01L 33/32

(52) U.S. Cl. CPC H01L 33/145; H01L 33/32

(57) ABSTRACT

A nitride semiconductor light-emitting element includes: an n-side semiconductor layer; one or more light-emitting layers disposed above the n-side semiconductor layer; a first barrier layer disposed above the one or more light-emitting layers and including Al; a second barrier layer disposed above the first barrier layer and including Al; a p-side guiding layer disposed above the second barrier layer and having an Al composition ratio smaller than an Al composition ratio of the second barrier layer; an electron blocking layer disposed above the p-side guiding layer, including Mg, and having an Al composition ratio larger than the Al composition ratio of the second barrier layer; and a p-side semiconductor layer disposed above the electron blocking layer.

### CROSS REFERENCE TO RELATED APPLICATIONS

This is a continuation-in-part application of PCT International Application No. PCT/JP2022/029988 filed on Aug. 4, 2022, designating the United States of America, which is based on and claims priority of Japanese Patent Application No. 2021-138405 filed on Aug. 26, 2021. The entire disclosures of the above-identified applications, including the specifications, drawings and claims are incorporated herein by reference in their entirety.

### FIELD

The present disclosure relates to a nitride semiconductor light-emitting element.

### BACKGROUND

Conventionally, nitride semiconductor light-emitting elements that emit blue light have been known (e.g., see Patent Literature (PTL) 1). However, there is a demand for a high-output, high-efficiency nitride semiconductor light-emitting elements that emit light having a wavelength shorter than the wavelength of blue light (i.e., light having a wavelength of less than or equal to 390 nm). Hereinafter, a nitride semiconductor light-emitting element that emits light having a wavelength of less than or equal to 390 nm is also called a short-wavelength nitride semiconductor light-emitting element.

### CITATION LIST

### Patent Literature

PTL 1: Japanese Unexamined Patent Application Publication No. 2002-335052

### SUMMARY

### Technical Problem

In a nitride semiconductor light-emitting element that emits blue light, an InGaN-based material is used for a light guiding layer, for example. As for a short-wavelength nitride semiconductor light-emitting element, an AlGaN-based material having band-gap energy larger than the band-gap energy of InGaN is used for a light guiding layer. Accordingly, the electrical resistance of the short-wavelength nitride semiconductor light-emitting element is larger than the electrical resistance of the nitride semiconductor light-emitting element that emits blue light. In addition, an activation rate of Mg that is added to a p-type AlGaN layer as an acceptor impurity reduces with an increase in Al composition ratio. Accordingly, hole injection efficiency of injecting holes into a light-emitting layer is reduced in the p-type AlGaN layer having a high Al composition ratio. When Mg is added to the proximity of the light-emitting layer to enhance the hole injection efficiency of injecting holes from the p-type AlGaN layer into the light-emitting layer, Mg is incorporated into the light-emitting layer due to thermal diffusion. For this reason, the number of non-radiative recombination centers in the light-emitting layer increases, thereby reducing light-emitting efficiency.

The present disclosure is intended to address the above-described problems, and aims to provide a nitride semiconductor that can prevent the incorporation of Mg into a light-emitting layer due to thermal diffusion, and can enhance hole injection efficiency of injecting holes into the light-emitting layer.

### Solution to Problem

In order to address the above-described problems, one aspect of a nitride semiconductor light-emitting element according to the present disclosure includes: an n-side semiconductor layer; one or more light-emitting layers disposed above the n-side semiconductor layer; a first barrier layer disposed above the one or more light-emitting layers and including Al; a second barrier layer disposed above the first barrier layer and including Al; a p-side guiding layer disposed above the second barrier layer and having an Al composition ratio smaller than an Al composition ratio of the second barrier layer; an electron blocking layer disposed above the p-side guiding layer, including Mg, and having an Al composition ratio larger than the Al composition ratio of the second barrier layer; and a p-side semiconductor layer disposed above the electron blocking layer.

### Advantageous Effects

According to the present disclosure, it is possible to provide a nitride semiconductor that can prevent the incorporation of Mg into a light-emitting layer due to thermal diffusion, and can enhance hole injection efficiency of injecting holes into the light-emitting layer.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic side view of the overall configuration of a nitride semiconductor light-emitting element according to Embodiment 1.

FIG. 2 is a graph showing an overview of a band diagram of a conduction band in a growth direction of the nitride semiconductor light-emitting element according to Embodiment 1.

FIG. 3 is a diagram schematically illustrating a band diagram and lattice constants of a conduction band from a first barrier layer to a p-side guiding layer according to Embodiment 1.

FIG. 4 is a diagram schematically illustrating a band diagram and lattice constants of a conduction band from a first barrier layer to a p-side guiding layer according to a comparative example.

FIG. 5 is a flowchart illustrating a manufacturing method of manufacturing the nitride semiconductor light-emitting element according to Embodiment 1.

FIG. 6 is a diagram illustrating a relationship between a time, a temperature, and supplied gas in each of manufacturing processes of manufacturing the nitride semiconductor light-emitting element according to Embodiment 1.

FIG. 7 is a graph showing an overview of a composition distribution in a layered direction of the nitride semiconductor light-emitting element according to Embodiment 1.

FIG. 8 is a schematic side view of the overall configuration of a nitride semiconductor light-emitting element according to a variation of Embodiment 1.

FIG. 9 is a schematic side view of the overall configuration of a nitride semiconductor light-emitting element according to Embodiment 6.

FIG. 10 is a graph showing a Mg concentration distribution from a second barrier layer to a p-side cladding layer of the nitride semiconductor light-emitting element according to Embodiment 6.

FIG. 11 is a graph showing Example 1 that is another example of the Mg concentration distribution from the second barrier layer to the p-side cladding layer of the nitride semiconductor light-emitting element according to Embodiment 6.

FIG. 12 is a graph showing Example 2 that is another example of the Mg concentration distribution from the second barrier layer to the p-side cladding layer of the nitride semiconductor light-emitting element according to Embodiment 6.

FIG. 13 is a schematic side view of the overall configuration of a nitride semiconductor light-emitting element according to Embodiment 7.

FIG. 14 is a flowchart illustrating forming processes of forming a p-side semiconductor layer in the nitride semiconductor light-emitting element according to Embodiment 7.

### DESCRIPTION OF EMBODIMENTS

Hereinafter, embodiments according to the present disclosure will be described with reference to the drawings. Note that the embodiments below each describe a specific example of the present disclosure. The numerical values, shapes, materials, elements, the arrangement and connection of the elements, etc. in the following embodiments are mere examples, and therefore do not intend to limit the present disclosure.

In addition, the drawings each are a schematic diagram, and do not necessarily provide strictly accurate illustration. Accordingly, the drawings do not necessarily coincide with one another in terms of scales and the like. Throughout the drawings, the same reference numeral is given to substantially the same structural element, and redundant description is omitted or simplified.

Moreover, in the present specification, the terms “above/upper” and “below/lower” do not refer to the vertically upward direction and vertically downward direction in terms of absolute spatial recognition, but are used as terms defined by relative positional relationships based on the layering order in a layered configuration. In addition, the terms “above/upper” and “below/lower” are applied not only when two elements are disposed spaced apart with another element interposed therebetween, but also when the two elements are disposed in contact with each other.

### Embodiment 1

A nitride semiconductor light-emitting element according to Embodiment 1 will be described.

### 1-1. Overall Configuration

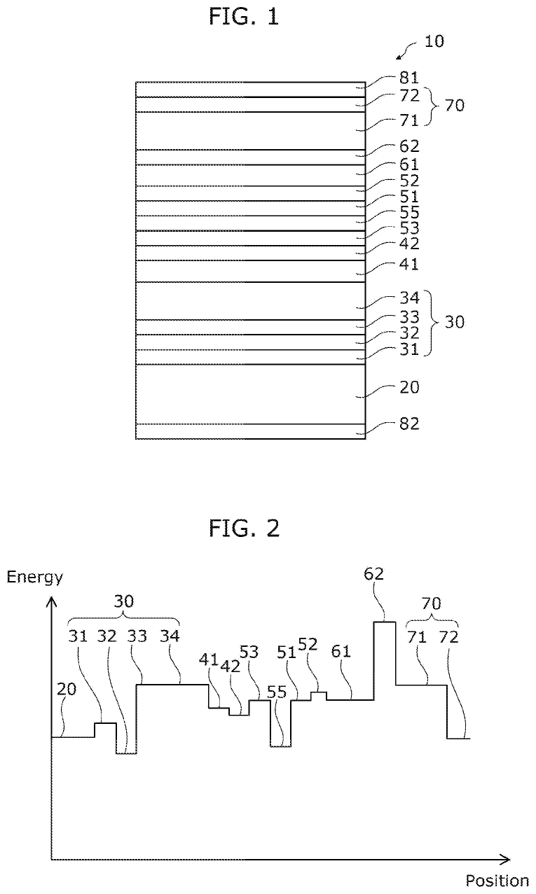

First, the overall configuration of a nitride semiconductor light-emitting element according to the present embodiment will be described with reference to FIG. 1 and FIG. 2. FIG. 1 is a schematic side view of the overall configuration of nitride semiconductor light-emitting element 10 according to the present embodiment. FIG. 2 is a graph showing an overview of a band diagram of a conduction band in the growth direction of nitride semiconductor light-emitting element 10 according to the present embodiment. The horizontal axis and vertical axis shown in FIG. 2 represent the position in the layered direction of nitride semiconductor light-emitting element 10 and energy, respectively. In the horizontal axis shown in FIG. 2, the direction from the left toward the right corresponds to the direction from a lower position toward an upper position in the layered direction (i.e., the crystal growth direction).

As illustrated in FIG. 1, nitride semiconductor light-emitting element 10 according to the present embodiment includes substrate 20, n-side semiconductor layer 30, first n-side guiding layer 41, second n-side guiding layer 42, third barrier layer 53, light-emitting layer 55, first barrier layer 51, second barrier layer 52, p-side guiding layer 61, electron blocking layer 62, p-side semiconductor layer 70, p-side electrode 81, and n-side electrode 82.

Substrate 20 is a plate-like member that is a base of nitride semiconductor light-emitting element 10. In the present embodiment, substrate 20 is an n-type GaN substrate.

N-side semiconductor layer 30 is a nitride semiconductor layer disposed above substrate 20. In the present embodiment, n-side semiconductor layer 30 is directly layered on the upper principal surface of substrate 20. N-side semiconductor layer 30 includes base layer 31, strain relaxation layer 32, capping layer 33, and n-side cladding layer 34.

Base layer 31 is an n-type nitride semiconductor layer disposed above substrate 20. In the present embodiment, base layer 31 is an n-type Al_{0.02}Ga_{0.98}N layer having a thickness of 1.5 μm. As an impurity, Si is added to base layer 31. Note that n-side semiconductor layer 30 need not include base layer 31.

Strain relaxation layer 32 is an n-type nitride semiconductor layer disposed above substrate 20. In the present embodiment, strain relaxation layer 32 is an n-type In_{0.03}Ga_{0.97}N layer that is disposed above base layer 31 and has a thickness of 0.2 μm. As an impurity, Si is added to strain relaxation layer 32. Note that n-side semiconductor layer 30 need not include strain relaxation layer 32.

Capping layer 33 is an n-type nitride semiconductor layer disposed above substrate 20. In the present embodiment, capping layer 33 is an n-type Al_{0.08}Ga_{0.92}N layer that is disposed above strain relaxation layer 32 and has a thickness of 10 nm. As an impurity, Si is added to capping layer 33. Note that n-side semiconductor layer 30 need not include capping layer 33.

N-side cladding layer 34 is an n-type nitride semiconductor layer disposed above substrate 20. In the present embodiment, n-side cladding layer 34 is an n-type Al_{0.08}Ga_{0.92}N layer that is disposed above capping layer 33 and has a thickness of 0.8 μm. As an impurity, Si is added to n-side cladding layer 34. N-side cladding layer 34 has a refractive index lower than the refractive index of each of light-emitting layer 55, first barrier layer 51, second barrier layer 52, and third barrier layer 53. With this, n-side cladding layer 34 prevents light produced in light-emitting layer 55 from passing through n-side cladding layer 34 to reach substrate 20. Note that n-side cladding layer 34 may be an AlInGaN layer or an AlInN layer. In addition, n-side cladding layer 34 may include a single layer having a uniform composition or may include a plurality of layers having different compositions. For example, n-side cladding layer 34 may have a superlattice structure. Specifically, n-side cladding layer 34 may have a configuration in which a plurality of AlGaN layers and a plurality of AlInGaN layers or a plurality of AlInN layers are alternately layered. Moreover, n-side cladding layer 34 may have a configuration in which two types of AlGaN layers having different Al composition ratios are alternately layered.

First n-side guiding layer 41 is a nitride semiconductor layer disposed above n-side semiconductor layer 30. First n-side guiding layer 41 has a refractive index higher than a refractive index of n-side cladding layer 34. In the present embodiment, first n-side guiding layer 41 is an n-type Al_{0.03}Ga_{0.97}N layer having a thickness of 0.12 μm. As an impurity, Si is added to first n-side guiding layer 41.

Second n-side guiding layer 42 is a nitride semiconductor layer disposed above n-side semiconductor layer 30. Second n-side guiding layer 42 has a refractive index higher than a refractive index of n-side cladding layer 34. In the present embodiment, second n-side guiding layer 42 is an undoped Al_{0.02}Ga_{0.98}N layer that is disposed above first n-side guiding layer 41 and has a thickness of 18 nm. Note that Si may be added to second n-side guiding layer 42 as an impurity.

Third barrier layer 53 is a nitride semiconductor layer disposed above n-side semiconductor layer 30, and is also called a lower barrier layer. Third barrier layer 53 is disposed in a position adjacent to light-emitting layer 55. In the present embodiment, third barrier layer 53 is an undoped Al_{0.08}Ga_{0.95}N layer that is disposed between second n-side guiding layer 42 and light-emitting layer 55 and has a thickness of 5 nm.

Light-emitting layer 55 is a nitride semiconductor layer that is disposed above n-side semiconductor layer 30 and emits light. In the present embodiment, light-emitting layer 55 is an undoped In_{0.01}Ga_{0.99}N layer that is disposed between third barrier layer 53 and first barrier layer 51 and has a thickness of 10 nm. Light-emitting layer 55 generates light having a wavelength of less than or equal to 390 nm. As described above, light-emitting layer 55 includes In, and the wavelength of light emitted by nitride semiconductor light-emitting element 10 is less than or equal to 390 nm. The wavelength of light that nitride semiconductor light-emitting element 10 emits may be more than or equal to 350 nm. In addition, the wavelength of light that nitride semiconductor light-emitting element 10 emits may range from 365 nm to 385 nm, both inclusive.

First barrier layer 51 is a nitride semiconductor layer that is disposed above light-emitting layer 55 and includes Al. First barrier layer 51 is also called an upper barrier layer. One example of the composition of first barrier layer 51 is expressed as Al_{X1}Ga_{1-X1}N, using Al composition ratio X1. In the present embodiment, first barrier layer 51 is an undoped Al_{0.05}Ga_{0.95}N layer that is disposed between light-emitting layer 55 and second barrier layer 52 and has a thickness of 5 nm. First barrier layer 51, third barrier layer 53, and light-emitting layer 55 may compose a quantum well structure.

Second barrier layer 52 is a nitride semiconductor layer that is disposed above first barrier layer 51 and includes Al. Second barrier layer 52 is also called a diffusion prevention layer. One example of the composition of second barrier layer 52 is expressed as Al_{X2}Ga_{1-X2}N, using Al composition ratio X2. Al composition ratio X2 of second barrier layer 52 is larger than Al composition ratio X1 of first barrier layer 51. In other words, the inequality X2>X1 holds true. With this, the band-gap energy of second barrier layer 52 is larger than the band-gap energy of first barrier layer 51, as illustrated in FIG. 2. In the present embodiment, second barrier layer 52 is an undoped Al_{0.07}Ga_{0.93}N layer that is disposed between first barrier layer 51 and p-side guiding layer 61 and has a thickness of 3 nm.

Second barrier layer 52 is thinner than first barrier layer 51. With this, an increase in the electrical resistance in second barrier layer 52 can be reduced. In the present embodiment, the thickness of second barrier layer 52 may range from 1 nm to 4 nm, both inclusive. Moreover, the Al composition ratio of second barrier layer 52 may be more than or equal to 6%. In addition, the Al composition ratio of second barrier layer 52 may be less than or equal to 10% for reducing an increase in the electrical resistance in second barrier layer 52. Furthermore, Al composition ratio X2 may satisfy the relation of 0.01≤X2−X1≤0.06.

P-side guiding layer 61 is a nitride semiconductor layer that is disposed above second barrier layer 52 and has an Al composition ratio smaller than the Al composition ratio of second barrier layer 52. In other words, the inequality Xpg<X2 holds true between Al composition ratio Xpg of p-side guiding layer 61 and Al composition ratio X2 of second barrier layer 52.

P-side guiding layer 61 has a refractive index higher than a refractive index of p-side semiconductor layer 70. In the present embodiment, p-side guiding layer 61 is a p-type Al_{0.05}Ga_{0.95}N layer that is disposed between second barrier layer 52 and electron blocking layer 62 and has a thickness of 50 nm. As an impurity, p-side guiding layer 61 includes Mg. In the present embodiment, Mg is added during a growth process of p-side guiding layer 61. An average Mg concentration in p-side guiding layer 61 may be lower than an average Mg concentration in electron blocking layer 62. For example, the average Mg concentration in p-side guiding layer 61 may be less than or equal to a tenth of the average Mg concentration in electron blocking layer 62. In addition, the Mg concentration in p-side guiding layer 61 in the vicinity of the interface far from electron blocking layer 62 may be lower than the Mg concentration in p-side guiding layer 61 in the vicinity of the interface near electron blocking layer 62. In other words, the Mg concentration in p-side guiding layer 61 in the vicinity of the interface near light-emitting layer 55 may be lower than the Mg concentration in p-side guiding layer 61 in the vicinity of the interface far from light-emitting layer 55. With this, the Mg concentration in p-side guiding layer 61 in the vicinity of the interface near light-emitting layer 55 can be reduced. Accordingly, an amount of Mg incorporated into light-emitting layer 55 due to thermal diffusion can be reduced. Since an increase in the number of non-radiative recombination centers in light-emitting layer 55 can be prevented, a reduction in light-emitting efficiency can therefore be prevented.

Electron blocking layer 62 is a nitride semiconductor layer that is disposed above p-side guiding layer 61, includes Mg, and has an Al composition ratio larger than the Al composition ratio of second barrier layer 52. One example of the composition of electron blocking layer 62 is expressed as Al_{Xe}Ga_{1-Xe}N, using Al composition ratio Xe. Electron blocking layer 62 has a function of preventing electrons that have passed through light-emitting layer 55 from moving to p-side semiconductor layer 70. With this, electrons can be trapped in the vicinity of light-emitting layer 55. In the present embodiment, electron blocking layer 62 is a p-type Al_{0.36}Ga_{0.64}N layer that is disposed between p-side guiding layer 61 and p-side semiconductor layer 70 and has a thickness of 5 nm. As an impurity, Mg is added to electron blocking layer 62. Al composition ratio Xe of electron blocking layer 62 is larger than an Al composition ratio Xp of p-side semiconductor layer 70. In other words, the inequality Xe>Xp holds true. With this, the band-gap energy of electron blocking layer 62 is larger than the band-gap energy of p-side semiconductor layer 70, as illustrated in FIG. 2.

P-side semiconductor layer 70 is a nitride semiconductor layer disposed above electron blocking layer 62. In the present embodiment, p-side semiconductor layer 70 includes p-side cladding layer 71 and contact layer 72.

P-side cladding layer 71 is a nitride semiconductor layer disposed above electron blocking layer 62. In the present embodiment, p-side cladding layer 71 is a p-type Al_{0.08}Ga_{0.92}N layer that is disposed between electron blocking layer 62 and contact layer 72 and has a thickness of 0.5 μm. As an impurity, Mg is added to p-side cladding layer 71. P-side cladding layer 71 has a refractive index lower than the refractive index of each of light-emitting layer 55, first barrier layer 51, second barrier layer 52, and third barrier layer 53. With this, p-side cladding layer 71 prevents light produced in light-emitting layer 55 from passing through p-side cladding layer 71. Note that p-side cladding layer 71 may be an AlInGaN layer or an AlInN layer. In addition, p-side cladding layer 71 may include a single layer having a uniform composition or may include a plurality of layers having different compositions. For example, p-side cladding layer 71 may have a superlattice structure. Specifically, p-side cladding layer 71 may have a configuration in which a plurality of AlGaN layers and a plurality of AlInGaN layers or a plurality of AlInN layers are alternately layered. Moreover, p-side cladding layer 71 may have a configuration in which two types of AlGaN layers having different Al compositions are alternately layered.

Contact layer 72 is a nitride semiconductor layer disposed above p-side cladding layer 71. A conductive film is disposed on contact layer 72, and contact layer 72 makes an ohmic contact with the conductive film. In the present embodiment, contact layer 72 is a p-type GaN layer having a thickness of 10 nm. Moreover, contact layer 72 may include Al. An Al composition ratio of contact layer 72 is smaller than an Al composition ratio of p-side cladding layer 71. Contact layer 72 may be, for example, an Al_{0.02}Ga_{0.98}N layer.

P-side electrode 81 is an electrode disposed above p-side semiconductor layer 70. P-side electrode 81 may include, for example, Ag. Ag included in p-side electrode 81 may make an ohmic contact with contact layer 72, for example. In other words, p-side electrode 81 may include an Ag film that makes an ohmic contact with contact layer 72. The use of Ag having a low refractive index for light having a wavelength of less than or equal to 390 nm in at least a portion of p-side electrode 81 can reduce seepage of light that propagates in light-emitting layer 55 and the vicinity thereof into p-side electrode 81. Accordingly, loss of light in p-side electrode 81 can be reduced. The refractive index of Ag is less than or equal to 0.5 within a wavelength range of from 325 nm to 1500 nm, both inclusive, and is less than or equal to 0.2 within a wavelength range of from 360 nm to 950 nm, both inclusive. In this case, seepage of light into p-side electrode 81 can be reduced even if the thickness of p-side cladding layer 71 is less than or equal to 0.4 μm. Accordingly, an increase in loss of light can be prevented while reducing series resistance of nitride semiconductor light-emitting element 10. N-side electrode 82 is an electrode disposed on the lower principal surface of substrate 20 (i.e., among the principal surfaces of nitride semiconductor light-emitting element 10, a principal surface on the back side of the principal surface on which n-side semiconductor layer 30 is layered).

### 1-2. Advantageous Effects

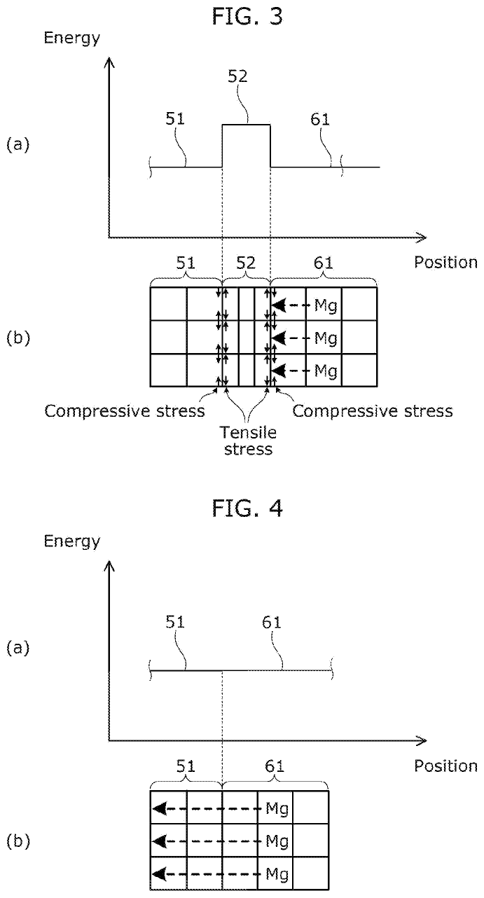

Next, advantageous effects of nitride semiconductor light-emitting element 10 according to the present embodiment will be described with reference to FIG. 3. FIG. 3 and FIG. 4 are each a diagram schematically illustrating a band diagram and lattice constants of a conduction band from first barrier layer 51 to p-side guiding layer 61 according to the present embodiment and a comparative example, respectively. Graph (a) in each of FIG. 3 and FIG. 4 is a graph showing an overview of a band diagram of the conduction band in a growth direction. Schematic diagram (b) in each of FIG. 3 and FIG. 4 is a diagram schematically illustrating a lattice constant of each of the layers and stresses generated in each layer. In each schematic diagram (b), the size (breadth) of a lattice represents the size of a lattice constant of each layer, and solid-line arrows each denote a stress direction. In addition, each schematic diagram (b) shows dashed-line arrows each denoting a range in which Mg moves due to thermal diffusion. The nitride semiconductor light-emitting element according to the comparative example shown in FIG. 4 is different from nitride semiconductor light-emitting element 10 according to the present embodiment in that the nitride semiconductor light-emitting element according to the comparative example does not include second barrier layer 52. Other than the foregoing, the nitride semiconductor light-emitting element according to the comparative example agrees with the nitride semiconductor light-emitting element 10 according to the present embodiment.

As illustrated in FIG. 4, the Al composition ratio and band-gap energy of first barrier layer 51 and the Al composition ratio and band-gap energy of p-side guiding layer 61 are equal in the nitride semiconductor light-emitting element not including second barrier layer 52. Accordingly, the lattice constant of first barrier layer 51 and the lattice constant of p-side guiding layer 61 are equal. Therefore, stress resulting from a difference between the lattice constants of first barrier layer 51 and p-side guiding layer 61 is not generated in the vicinity of the interface between first barrier layer 51 and p-side guiding layer 61. For this reason, Mg included in p-side guiding layer 61 moves to first barrier layer 51 due to thermal diffusion. In addition, Mg that moved to first barrier layer 51 further moves to light-emitting layer 55 disposed below first barrier layer 51 due to thermal diffusion. For this reason, the number of non-radiative recombination centers in light-emitting layer is increased, thereby reducing light-emitting efficiency.

Alternatively, nitride semiconductor light-emitting element 10 according to the present embodiment includes, between p-side guiding layer 61 and first barrier layer 51, second barrier layer 52 having the Al composition ratio and band-gap energy larger than the Al composition ratio and band-gap energy of p-side guiding layer 61 and first barrier layer 51. In this case, as illustrated in schematic diagram (b) shown in FIG. 3, the lattice constant of second barrier layer 52 is smaller than the lattice constants of p-side guiding layer 61 and first barrier layer 51. For this reason, stresses are generated in the vicinity of the interface between p-side guiding layer 61 and second barrier layer 52. Compressive stress is generated in the vicinity of the interface between p-side guiding layer 61 and second barrier layer 52 on the p-side guiding layer 61 side, and tensile stress is generated in the vicinity of the interface between second barrier layer 52 and p-side guiding layer 61 on the second barrier layer 52 side. In addition, tensile stress is generated in the vicinity of the interface between second barrier layer 52 and first barrier layer 51 on the second barrier layer 52 side, and compressive stress is generated in the vicinity of the interface between first barrier layer 51 and second barrier layer 52 on the first barrier layer 51 side.

In this case, it is typically known that the diffusion of Mg is prevented in a region where a compressive stress region and a tensile stress region are disposed in the stated order as viewed from Mg included in p-side guiding layer 61, just like the vicinity of the interface (hetero interface) between p-side guiding layer 61 and second barrier layer 52. With this, nitride semiconductor light-emitting element 10 according to the present embodiment can prevent Mg included in p-side guiding layer 61 from moving to first barrier layer 51 and light-emitting layer 55 due to thermal diffusion. Since an increase in the number of non-radiative recombination centers in light-emitting layer 55 can be prevented, a reduction in light-emitting efficiency can therefore be prevented.

Note that, in the above-described comparative example, the Al composition ratio and band-gap energy of first barrier layer 51 and the Al composition ratio and band-gap energy of p-side guiding layer 61 are equal. However, Mg still moves from p-side guiding layer 61 to first barrier layer 51 and light-emitting layer 55 due to thermal diffusion even if the Al composition ratio and band-gap energy of first barrier layer 51 are smaller than the Al composition ratio and band-gap energy of p-side guiding layer 61. In other words, diffusion of Mg is not prevented in a region in which a tensile stress region and a compressive stress region are disposed in the stated order as viewed from Mg included in p-side guiding layer 61.

Moreover, since second barrier layer 52 included in nitride semiconductor light-emitting element 10 according to the present embodiment is thinner than first barrier layer 51, a distance between p-side guiding layer 61 including Mg and light-emitting layer 55 can be reduced. In other words, Mg can be added to the vicinity of light-emitting layer 55. Therefore, it is possible to enhance hole injection efficiency of injecting holes into light-emitting layer 55. In addition, making second barrier layer 52 thin can prevent an increase in the electrical resistance in second barrier layer 52. With this, series resistance of nitride semiconductor light-emitting element 10 can be reduced.

As has been described above, nitride semiconductor light-emitting element 10 according to the present embodiment can prevent incorporation of Mg into light-emitting layer 55 due to thermal diffusion, and can enhance hole injection efficiency of injecting holes into light-emitting layer 55.

### 1-3. Manufacturing Method

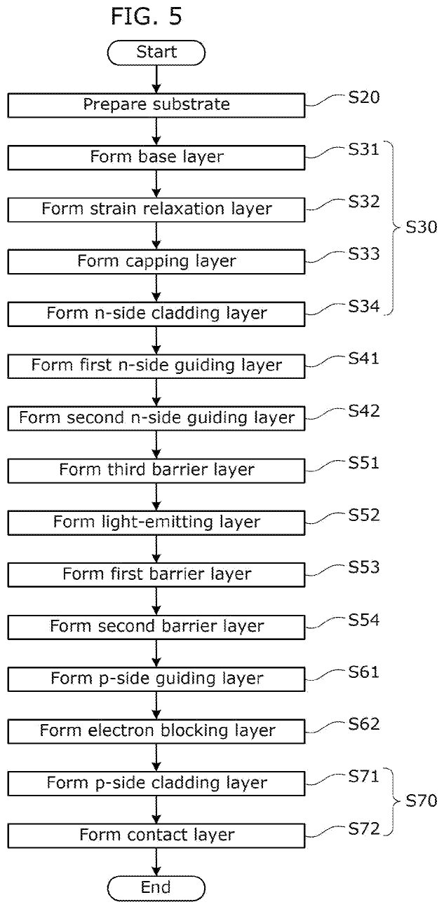

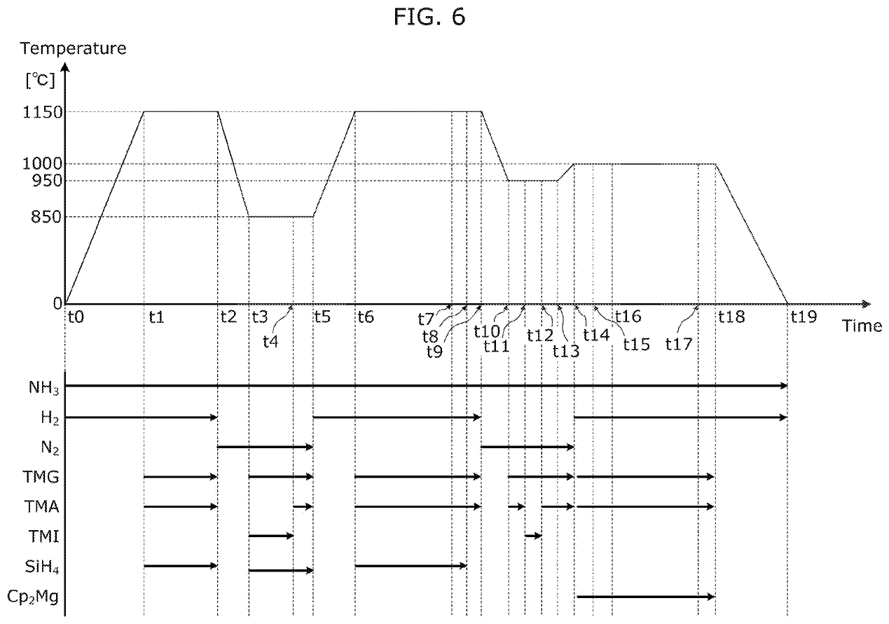

Next, an example of a manufacturing method of manufacturing nitride semiconductor light-emitting element 10 according to the present embodiment will be described with reference to FIG. 5 and FIG. 6. FIG. 5 is a flowchart illustrating a manufacturing method of manufacturing nitride semiconductor light-emitting element 10 according to the present embodiment. FIG. 6 is a diagram illustrating a relationship between a time, a temperature, and supplied gas in each of manufacturing processes of manufacturing nitride semiconductor light-emitting element 10 according to the present embodiment.

As illustrated in FIG. 5, substrate 20 is prepared (S20) in the first place, and substrate 20 is set inside a device for crystal growth. In the present embodiment, a GaN substrate is prepared as substrate 20. Moreover, a metalorganic chemical vapor deposition (MOCVD) device is used as the device for crystal growth in the present embodiment. Then, NH₃ and H₂ are supplied inside the device for crystal growth in which substrate 20 is set, and the temperature of substrate 20 is increased to 1150° C. (see from time point to t0 time point t1 shown in FIG. 6).

Then, n-side semiconductor layer 30 is formed (S30). Among the layers included in n-side semiconductor layer 30, base layer 31 is formed in the first place (S31). In the present embodiment, trimethylgallium (TMG), trimethylaluminum (TMA), and SiH₄ are supplied inside the device for crystal growth to cause base layer 31 including n-type Al_{0.02}Ga_{0.98}N and having a thickness of 1.5 μm to grow on substrate 20 (see from time point t1 to time point t2 shown in FIG. 6). Next, strain relaxation layer 32 is formed (S32). Specifically, the supply of TMG, TMA, and SiH₄ is stopped after the completion of forming base layer 31, and the supply of N₂ is started. In addition, the temperature of substrate 20 is reduced to 850° C. (see from time point t2 to time point t3 shown in FIG. 6). Then, TMG, trimethylindium (TMI), and SiH₄ are supplied inside the device for crystal growth to cause strain relaxation layer 32 including n-type In_{0.03}Ga_{0.97}N and having a thickness of 0.2 μm to grow on base layer 31 (see from time point t3 to time point t4 shown in FIG. 6). Next, capping layer 33 is formed (S33). Specifically, the supply of TMI is stopped after the completion of forming strain relaxation layer 32, and the supply of TMA is started to cause capping layer 33 including n-type Al_{0.08}Ga_{0.92}N and having a thickness of 10 nm to grow on strain relaxation layer 32 (see from time point t4 to time point t5 shown in FIG. 6). Next, n-side cladding layer 34 is formed (S34). Specifically, the supply of TMG, TMA, SiH₄, and N₂ is stopped after the completion of forming capping layer 33, and the supply of H₂ is started. In addition, the temperature of substrate 20 is increased to 1150° C. (see from time point t5 to time point t6 shown in FIG. 6). Then, TMG, TMA, and SiH₄ are supplied inside the device for crystal growth to cause n-side cladding layer 34 including n-type Al_{0.08}Ga_{0.92}N and having a thickness of 0.8 μm to grow on capping layer 33 (see from time point t6 to time point t7 shown in FIG. 6).

Then, first n-side guiding layer 41 is formed (S41). Specifically, the supply amount of TMA supplied to the device for crystal growth is reduced to cause first n-side guiding layer 41 including n-type Al_{0.03}Ga_{0.97}N and having a thickness of 12 μm to grow on n-side cladding layer 34 (see from time point t7 to time point t8 shown in FIG. 6).

Then, second n-side guiding layer 42 is formed (S42). Specifically, the supply amount of TMA supplied to the device for crystal growth is further reduced, and the supply of SiH₄ is stopped to cause second n-side guiding layer 42 including undoped Al_{0.02}Ga_{0.98}N and having a thickness of 18 nm to grow on first n-side guiding layer 41 (see from time point t8 to time point t9 shown in FIG. 6).

Then, third barrier layer 53 is formed (S51). Specifically, the supply of TMG, TMA, and H₂ is stopped and the supply of N₂ is started. In addition, the temperature of substrate 20 is reduced to 950° C. (see from time point t9 to time point t10 shown in FIG. 6). Then, TMG and TMA are supplied inside the device for crystal growth to cause third barrier layer 53 including undoped Al_{0.05}Ga_{0.95}N and having a thickness of 5 nm to grow on second n-side guiding layer 42 (see from time point t10 to time point t11 shown in FIG. 6).

Then, light-emitting layer 55 is formed (S52). Specifically, the supply of TMA to the device for crystal growth is stopped, and the supply of TMI is started to cause light-emitting layer 55 including undoped In_{0.01}Ga_{0.99}N and having a thickness of 10 nm to grow on third barrier layer 53 (see from time point t11 to time point t12 shown in FIG. 6). The thickness of light-emitting layer 55 is not limited to 10 nm. The thickness of light-emitting layer 55 is to be determined in accordance with laser properties (the wavelength, output, etc.). For example, the thickness of light-emitting layer 55 is to be determined within a range of from 3 nm to 20 nm, both inclusive.

Then, first barrier layer 51 is formed (S53). Specifically, the supply of TMI to the device for crystal growth is stopped, and the supply of TMA is started to cause first barrier layer 51 including undoped Al_{0.08}Ga_{0.95}N and having a thickness of 5 nm to grow on light-emitting layer 55 (see from time point t12 to time point t13 shown in FIG. 6).

Then, second barrier layer 52 is formed (S54). Specifically, the supply amount of TMA supplied to the device for crystal growth is increased to cause second barrier layer 52 including undoped Al_{0.07}Ga_{0.93}N and having a thickness of 3 nm to grow on first barrier layer 51, while increasing the temperature of substrate 20 to 1000° C. (see from time point t13 to time point t14 shown in FIG. 6).

Then, p-side guiding layer 61 is formed (S61). Specifically, the supply of TMG and TMA to the device for crystal growth is stopped. Furthermore, the supply of N₂ is stopped, and the supply of H₂ is immediately started. Then, the supply of TMG, TMA, and Cp₂Mg is started to cause p-side guiding layer 61 including p-type Al_{0.05}Ga_{0.95}N and having a thickness of 50 nm to grow on second barrier layer 52 (see from time point t14 to time point t15 shown in FIG. 6).

Then, electron blocking layer 62 is formed (S62). Specifically, the supply amount of TMA supplied to the device for crystal growth is increased to cause electron blocking layer 62 including p-type Al_{0.36}Ga_{0.64}N and having a thickness of 5 nm to grow on p-side guiding layer 61 (see from time point t15 to time point t16 shown in FIG. 6).

Then, p-side semiconductor layer 70 is formed (S70). Among the layers included in p-side semiconductor layer 70, p-side cladding layer 71 is formed in the first place (S71). Specifically, the supply amount of TMA supplied to the device for crystal growth is reduced to cause p-side cladding layer 71 including p-type Al_{0.08}Ga_{0.92}N and having a thickness of 0.5 μm to grow on electron blocking layer 62 (see from time point t16 to time point t17 shown in FIG. 6). Next, contact layer 72 is formed (S72). Specifically, the supply of TMA to the device for crystal growth is stopped, and the supply amount of Cp₂Mg is increased to cause contact layer 72 including p-type GaN and having a thickness of 10 nm to grow on p-side cladding layer 71 (see from time point t17 to time point t18 shown in FIG. 6). Then, after the temperature of substrate 20 is reduced to a room temperature while supplying NH₃ and H₂ (see time point t18 to time point t19 shown in FIG. 6), substrate 20 above which each semiconductor layer is layered is taken out from the device for crystal growth.

As has been described above, nitride semiconductor light-emitting element 10 according to the present embodiment can be manufactured.

Note that the manufacturing method of manufacturing nitride semiconductor light-emitting element 10 according to the present embodiment is not limited to the above-described method. For example, although a GaN substrate was prepared as substrate 20, other nitride semiconductor substrates, such as an AlGaN substrate, may be prepared.

In addition, TMA may be additionally supplied to the device for crystal growth when strain relaxation layer 32 is formed to form strain relaxation layer 32 including n-type In_{0.03}Al_{0.02}Ga_{0.95}N.

Moreover, TMA may be additionally supplied to the device for crystal growth when light-emitting layer 55 is formed to form light-emitting layer 55 including undoped In_{0.01}Al_{0.02}Ga_{0.97}N.

In addition, formation of capping layer 33 of nitride semiconductor light-emitting element 10 may be omitted. In this case, the supply of TMG, TMA, SIH₄, and N₂ is to be stopped after forming strain relaxation layer 32, and the supply of H₂ is to be started. Then, after the temperature of substrate 20 is increased to 1150° C., n-side cladding layer 34 is to be formed in the same manner as the above-described manufacturing method.

Moreover, in the above-described manufacturing method, second barrier layer 52 was formed while increasing the temperature of substrate 20. However, the temperature of substrate 20 may be increased after second barrier layer 52 is formed, or second barrier layer 52 may be formed after the temperature of substrate 20 is increased. Specifically, after forming first barrier layer 51, the supply amount of TMA supplied to the device for crystal growth may be increased to form second barrier layer 52 including undoped Al_{0.07}Ga_{0.93}N and having a thickness of 3 nm, and then the temperature of substrate 20 may be increased to 1000° C. Alternatively, after forming first barrier layer 51, the supply of TMG, TMA, and N₂ may be stopped and the supply of H₂ may be started. Then, after the temperature of substrate 20 is increased to 1000° C., TMG and TMA may be supplied to the device for crystal growth to form second barrier layer 52 including undoped Al_{0.07}Ga_{0.93}N and having a thickness of 3 nm.

In addition, temperatures of substrate 20 in the above-described manufacturing method are mere examples. Accordingly, the temperatures of substrate 20 in the above-described manufacturing method of manufacturing nitride semiconductor light-emitting element 10 according to the present embodiment are not limited to the above-described temperatures.

### 1-4. Composition Distribution

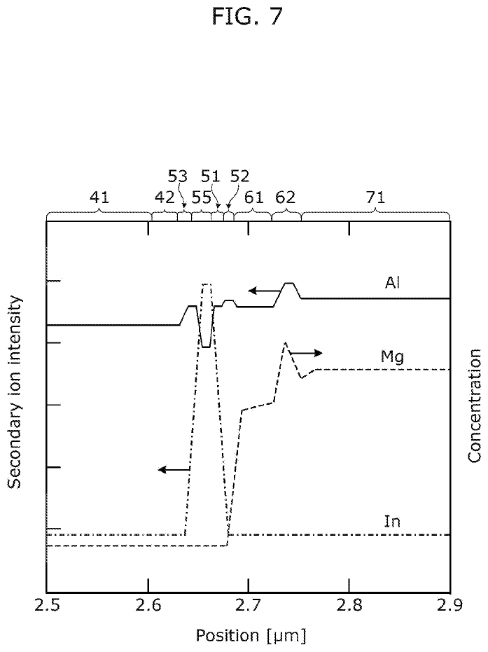

Next, a composition distribution in a layered direction of nitride semiconductor light-emitting element 10 according to the present embodiment will be described with reference to FIG. 7. FIG. 7 is a graph showing an overview of a composition distribution in the layered direction of nitride semiconductor light-emitting element 10 according to the present embodiment. FIG. 7 shows secondary ion intensities corresponding to Al and In which are measured using secondary ion mass spectrometry (SIMS), and Mg concentration. In FIG. 7, the horizontal axis represents the position in the layered direction of nitride semiconductor light-emitting element 10, the vertical axis on the left represents secondary ion intensities, and the vertical axis on the right represents concentration. The secondary ion intensities correspond to the composition ratios of Al and In.

The position shown in FIG. 7 at which the secondary ion intensity of In is maximum corresponds to light-emitting layer 55, and the position at which the secondary ion intensity of Al and Mg concentration are maximum corresponds to electron blocking layer 62. In the present embodiment, the average Mg concentration in electron blocking layer 62 is about 1×10¹⁹ [cm⁻³], and the average Mg concentration in p-side guiding layer 61 ranges from about 1×10¹⁷ [cm⁻³] to about at most 3×10¹⁸ [cm⁻³], both inclusive. The average Mg concentration in p-side cladding layer 71 is about 8×10¹⁸ [cm⁻³]. The average Mg concentrations in first barrier layer 51 and second barrier layer 52 are lower than the average Mg concentration in p-side guiding layer 61, and are less than a tenth of the average Mg concentration in p-side cladding layer 71.

As described above, in nitride semiconductor light-emitting element 10 according to the present embodiment, second barrier layer 52 can prevent Mg from moving from p-side guiding layer 61 to first barrier layer 51 due to thermal diffusion.

### Variation of Embodiment 1

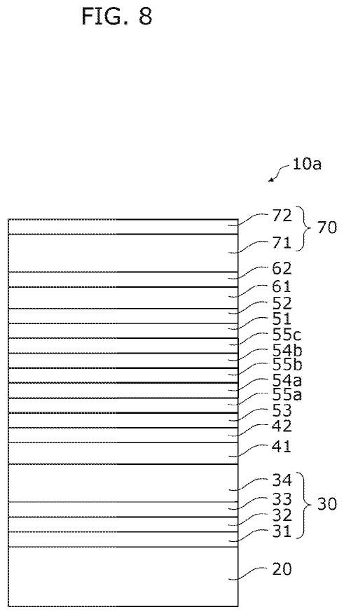

A nitride semiconductor light-emitting element according to a variation of Embodiment 1 will be described. The nitride semiconductor light-emitting element according to the variation is different from nitride semiconductor light-emitting element 10 according to Embodiment 1 in that the nitride semiconductor light-emitting element according to the variation includes a plurality of light-emitting layers. Hereinafter, the nitride semiconductor light-emitting element according to the variation will be described with reference to FIG. 8, focusing on the differences from nitride semiconductor light-emitting element 10 according to Embodiment 1.

FIG. 8 is a schematic side view of the overall configuration of nitride semiconductor light-emitting element 10a according to the variation. As illustrated in FIG. 8, nitride semiconductor light-emitting element 10a according to the variation includes substrate 20, n-side semiconductor layer 30, first n-side guiding layer 41, second n-side guiding layer 42, third barrier layer 53, light-emitting layers 55a, 55b, and 55c, fourth barrier layers 54a and 54b, first barrier layer 51, second barrier layer 52, p-side guiding layer 61, electron blocking layer 62, and p-side semiconductor layer 70.

Light-emitting layers 55a through 55c are nitride semiconductor layers disposed above n-side semiconductor layer 30, and emit light. Light-emitting layer 55a is an undoped In_{0.01}Ga_{0.99}N layer that is disposed between third barrier layer 53 and fourth barrier layer 54a and has a thickness of 5 nm. Light-emitting layer 55b is an undoped In_{0.01}Ga_{0.99}N layer that is disposed between fourth barrier layer 54a and fourth barrier layer 54b and has a thickness of 5 nm. Light-emitting layer 55c is an undoped In_{0.01}Ga_{0.99}N layer that is disposed between fourth barrier layer 54b and first barrier layer 51 and has a thickness of 5 nm.

Fourth barrier layers 54a and 54b are nitride semiconductor layers disposed above n-side semiconductor layer 30, and are also called intermediate barrier layers. Each of fourth barrier layers 54a and 54b is disposed between two adjacent light-emitting layers among light-emitting layers 55a through 55c. In this variation, fourth barrier layer 54a is an undoped Al_{0.03}Ga_{0.97}N layer that is disposed between light-emitting layer 55a and light-emitting layer 55b and has a thickness of 3 nm. Fourth barrier layer 54b is an undoped Al_{0.03}Ga_{0.97}N layer that is disposed between light-emitting layer 55b and light-emitting layer 55c and has a thickness of 3 nm.

Light-emitting layers 55a through 55c, first barrier layer 51, third barrier layer 53, and fourth barrier layers 54a and 54b according to the variation compose a multiple quantum well structure.

Nitride semiconductor light-emitting element 10a having the above-described configuration also produces the same advantageous effects as nitride semiconductor light-emitting element 10 according to Embodiment 1.

Next, the manufacturing method of manufacturing nitride semiconductor light-emitting element 10a according to the variation will be described.

Light-emitting layers 55a through 55c are formed in the same manner as light-emitting layer 55 according to Embodiment 1. In addition, fourth barrier layers 54a and 54b are formed in the same manner as first barrier layer 51 according to Embodiment 1.

Specifically, layers from n-side semiconductor layer 30 to third barrier layer 53 are formed in the same manner as respective layers of nitride semiconductor light-emitting element 10 according to Embodiment 1. Then, the supply of TMA supplied to the device for crystal growth when third barrier layer 53 is formed is stopped, and the supply of TMI is started to cause light-emitting layer 55a including undoped In_{0.01}Ga_{0.99}N and having a thickness of 5 nm to grow on third barrier layer 53.

Then, the supply of TMI to the device for crystal growth is stopped, and the supply of TMA is started to cause fourth barrier layer 54a including undoped Al_{0.03}Ga_{0.97}N and having a thickness of 3 nm to grow on light-emitting layer 55a.

Then, the supply of TMA to the device for crystal growth is stopped, and the supply of TMI is started to cause light-emitting layer 55b including undoped In_{0.01}Ga_{0.99}N and having a thickness of 5 nm to grow on fourth barrier layer 54a.

Then, the supply of TMI to the device for crystal growth is stopped, and the supply of TMA is started to cause fourth barrier layer 54b including undoped Al_{0.03}Ga_{0.97}N and having a thickness of 3 nm to grow on light-emitting layer 55b.

Then, the supply of TMA to the device for crystal growth is stopped, and the supply of TMI is started to cause light-emitting layer 55c including undoped In_{0.01}Ga_{0.99}N and having a thickness of 5 nm to grow on fourth barrier layer 54b.

Thereafter, first barrier layer 51, etc. are formed in the same manner as respective layers of nitride semiconductor light-emitting element 10 according to Embodiment 1, and nitride semiconductor light-emitting element 10a according to the variation can be manufactured.

Note that TMA may be additionally supplied to the device for crystal growth when light-emitting layers 55a through 55c are formed to form light-emitting layers 55a through 55c that include undoped In_{0.01}Al_{0.02}Ga_{0.97}N.

### Embodiment 2

A nitride semiconductor light-emitting element according to Embodiment 2 will be described. The nitride semiconductor light-emitting element according to the present embodiment is different from nitride semiconductor light-emitting element 10 according to Embodiment 1 in the composition of a p-side guiding layer. Hereinafter, the nitride semiconductor light-emitting element according to the present embodiment will be described, focusing on the differences from nitride semiconductor light-emitting element 10 according to Embodiment 1.

Other than the composition of the p-side guiding layer, the nitride semiconductor light-emitting element according to the present embodiment has the same configuration as nitride semiconductor light-emitting element 10 according to Embodiment 1. In nitride semiconductor light-emitting element 10 according to Embodiment 1, the Al composition ratio of p-side guiding layer 61 is exactly the same as the Al composition ratio of first barrier layer 51. However, in the nitride semiconductor light-emitting element according to the present embodiment, the Al composition ratio of the p-side guiding layer is different from the Al composition ratio of a first barrier layer. The p-side guiding layer according to the present embodiment is a p-type Al_{0.06}Ga_{0.94}N layer having a thickness of 50 nm. As described above, the Al composition ratio of the p-side guiding layer is to be smaller than the Al composition ratio of a second barrier layer, and may be different from the Al composition ratio of the first barrier layer.

As described above, the nitride semiconductor light-emitting element in which the Al composition ratio of the p-side guiding layer and the Al composition ratio of first barrier layer 51 are different also produces the same advantageous effects as nitride semiconductor light-emitting element 10 according to Embodiment 1.

Note that although the above has presented an example in which the Al composition ratio of the p-side guiding layer is larger than the Al composition ratio of first barrier layer 51, the Al composition ratio of the p-side guiding layer may be smaller than the Al composition ratio of first barrier layer 51. The p-side guiding layer may be, for example, a p-type Al_{0.04}Ga_{0.96}N layer having a thickness of 50 nm.

### Embodiment 3

A nitride semiconductor light-emitting element according to Embodiment 3 will be described. The nitride semiconductor light-emitting element according to the present embodiment is different from nitride semiconductor light-emitting element 10 according to Embodiment 1 in the configuration of a second barrier layer. Hereinafter, the nitride semiconductor light-emitting element according to the present embodiment will be described, focusing on the differences from nitride semiconductor light-emitting element 10 according to Embodiment 1.

Other than the configuration of the second barrier layer, the nitride semiconductor light-emitting element according to the present embodiment has the same configuration as nitride semiconductor light-emitting element 10 according to Embodiment 1.

The second barrier layer according to the present embodiment is an undoped Al_{0.10}Ga_{0.90}N layer having a thickness of 1 nm. As described above, the Al composition ratio of the second barrier layer is not limited to the Al composition ratio (0.07) of second barrier layer 52 according to Embodiment 1. When the Al composition ratio is larger than the Al composition ratio of second barrier layer 52 according to Embodiment 1 like the second barrier layer according to the present embodiment, the thickness of the second barrier layer may be less than the thickness of second barrier layer 52 according to embodiment 1. With this, an increase in the electrical resistance in the second barrier layer can be prevented.

The nitride semiconductor light-emitting element according to the present embodiment having the above-described configuration also produces the same advantageous effects as nitride semiconductor light-emitting element 10 according to Embodiment 1.

### Embodiment 4

A nitride semiconductor light-emitting element according to Embodiment 4 will be described. The nitride semiconductor light-emitting element according to the present embodiment is different from nitride semiconductor light-emitting element 10 according to Embodiment 1 in the configuration of a p-side guiding layer. Hereinafter, the nitride semiconductor light-emitting element according to the present embodiment will be described, focusing on the differences from nitride semiconductor light-emitting element 10 according to Embodiment 1.

Other than the configuration of the p-side guiding layer, the nitride semiconductor light-emitting element according to the present embodiment has the same configuration as nitride semiconductor light-emitting element 10 according to Embodiment 1.

Like p-side guiding layer 61 according to Embodiment 1, the p-side guiding layer according to the present embodiment is a p-type Al_{0.05}Ga_{0.95}N layer having a thickness of 50 nm. The p-side guiding layer according to the present embodiment is different from p-side guiding layer 61 according to Embodiment 1 in a formation method. In the present embodiment, gas including Mg, such as Cp₂Mg, is not supplied when growing a crystal of the p-side guiding layer. Mg is supplied to the p-side guiding layer due to thermal diffusion from an electron blocking layer. With this, the p-side guiding layer having the average Mg concentration lower than the average Mg concentration of the electron blocking layer can be formed. In addition, in the p-side guiding layer according to the present embodiment, the Mg concentration in the p-side guiding layer in the vicinity of the interface far from the electron blocking layer is also lower than the Mg concentration in the p-side guiding layer in the vicinity of the interface near the electron blocking layer, just like p-side guiding layer 61 according to Embodiment 1. Moreover, the average Mg concentration in the p-side guiding layer may be less than a tenth of the average Mg concentration in the electron blocking layer, for example.

The nitride semiconductor light-emitting element according to the present embodiment having the above-described configuration also produces the same as advantageous effects nitride semiconductor light-emitting element 10 according to Embodiment 1.

### Embodiment 5

A nitride semiconductor light-emitting element according to Embodiment 5 will be described. The nitride semiconductor light-emitting element according to the present embodiment is different from nitride semiconductor light-emitting element 10 according to Embodiment 1 in the configuration of a second barrier layer. Hereinafter, the nitride semiconductor light-emitting element according to the present embodiment will be described, focusing on the differences from nitride semiconductor light-emitting element 10 according to Embodiment 1.

Other than the configuration of the second barrier layer, the nitride semiconductor light-emitting element according to the present embodiment has the same configuration as nitride semiconductor light-emitting element 10 according to Embodiment 1.

The second barrier layer according to the present embodiment is an Al_{X2}Ga_{1-X2}N layer having a thickness of 3 nm. In the second barrier layer according to the present embodiment, the Al composition ratio is non-uniform. Al composition ratio X2 of the second barrier layer according to the present embodiment increases with a decrease in distance from a p-side guiding layer. In the present embodiment, Al composition ratio X2 of the second barrier layer in the vicinity of the interface far from the p-side guiding layer is 0.05 (5%), and Al composition ratio X2 of the second barrier layer in the vicinity of the interface near the p-side guiding layer is 0.07 (7%). Note that Al composition ratio X2 of the second barrier layer may be changed at a uniform rate of change in the layered direction, or may be changed stepwise in the layered direction. In addition, the configuration of the second barrier layer is not limited to the configuration in which Al composition ratio X2 is non-uniform across the entirety of the second barrier layer, but may be a configuration in which Al composition ratio X2 is non-uniform in part of the second barrier layer. In other words, the second barrier layer may include a region in which Al composition ratio X2 is non-uniform. For example, the second barrier layer may include a region in which Al composition ratio X2 increases with a decrease in distance from the p-side guiding layer.

The nitride semiconductor light-emitting element according to the present embodiment having the above-described configuration also produces the same advantageous effects as nitride semiconductor light-emitting element 10 according to Embodiment 1.

### Embodiment 6

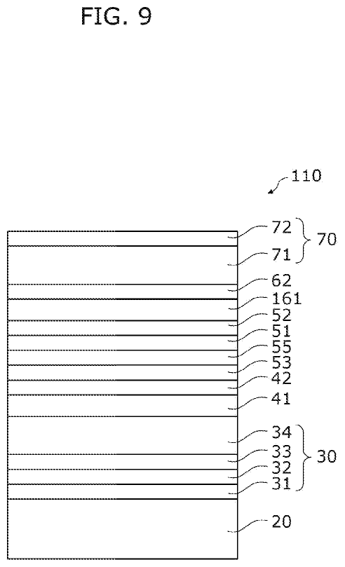

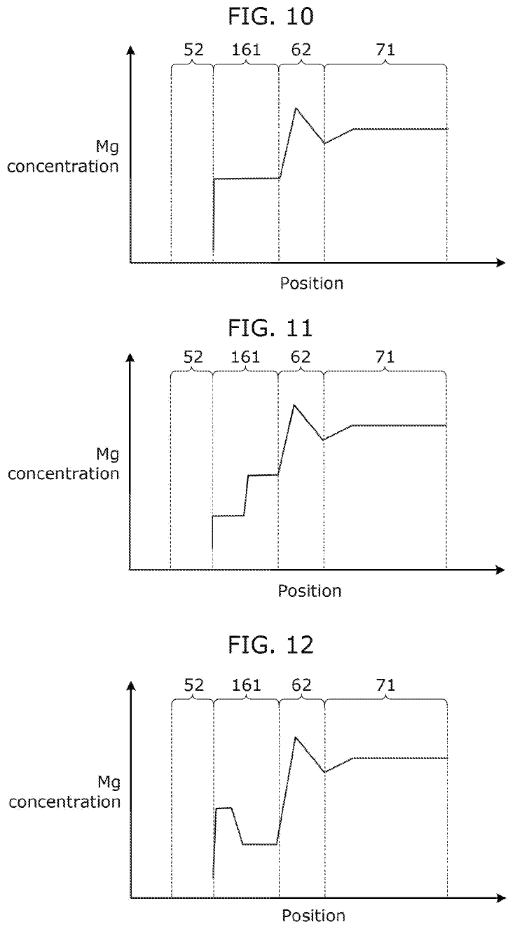

A nitride semiconductor light-emitting element according to Embodiment 6 will be described. The nitride semiconductor light-emitting element according to the present embodiment is different from nitride semiconductor light-emitting element 10 according to Embodiment 1 in the Mg concentration distribution in a p-side guiding layer. Hereinafter, the nitride semiconductor light emitting element according to the present embodiment will be described with reference to FIG. 9 and FIG. 10, focusing on the differences from nitride semiconductor light-emitting element 10 according to Embodiment 1.

FIG. 9 is a schematic side view of the overall configuration of nitride semiconductor light-emitting element 110 according to the present embodiment. FIG. 10 is a graph showing a Mg concentration distribution from second barrier layer 52 to p-side cladding layer 71 in nitride semiconductor light-emitting element 110 according to the present embodiment. In FIG. 10, the horizontal axis represents the position in the layered direction of nitride semiconductor light-emitting element 110, and the vertical axis represents Mg concentration.

As illustrated in FIG. 9, nitride semiconductor light-emitting element 110 according to the present embodiment includes substrate 20, n-side semiconductor layer 30, first n-side guiding layer 41, second n-side guiding layer 42, third barrier layer 53, light-emitting layer 55, first barrier layer 51, second barrier layer 52, p-side guiding layer 161, electron blocking layer 62, and p-side semiconductor layer 70.

Like p-side guiding layer 61 according to Embodiment 1, p-side guiding layer 161 according to the present embodiment is a p-type Al_{0.08}Ga_{0.95}N layer having a thickness of 50 nm. The average Mg concentration in p-side guiding layer 161 is lower than the average Mg concentration in electron blocking layer 62.

P-side guiding layer 161 according to the present embodiment is different from p-side guiding layer 61 according to Embodiment 1 in the Mg concentration distribution. The Mg concentration in p-side guiding layer 161 according to the present embodiment is uniform in the layered direction as shown in FIG. 10. Here, a configuration in which the Mg concentration is uniform is not limited to the configuration in which Mg is perfectly and uniformly distributed throughout p-side guiding layer 161, but includes a configuration in which Mg is substantially and uniformly distributed. For example, the configuration in which the Mg configuration is uniform may include a configuration in which the variation range of the Mg concentration is less than 10% of the average Mg concentration in p-side guiding layer 161.

Nitride semiconductor light-emitting element 110 according to the present embodiment having the above-described configuration also produces the same advantageous effects as nitride semiconductor light-emitting element 10 according to Embodiment 1.

Note that the Mg concentration distribution in p-side guiding layer 161 is not limited to the above-described examples. Hereinafter, other examples of the Mg concentration distribution in p-side guiding layer 161 will be described with reference to FIG. 11 and FIG. 12. FIG. 11 and FIG. 12 each are a graph showing another example of the Mg concentration distribution from second barrier layer 52 to p-side cladding layer 71 in nitride semiconductor light-emitting element 110 according to the present embodiment.

As illustrated in FIG. 11, the Mg concentration in p-side guiding layer 161 may be increased stepwise with a decrease in distance from electron blocking layer 62.

In addition, as illustrated in FIG. 12, the Mg concentration in p-side guiding layer 161 in the vicinity of the interface far from electron blocking layer 62 may be higher than the Mg concentration in p-side guiding layer 161 in the vicinity of the interface near electron blocking layer 62. In the example shown in FIG. 12, the Mg concentration in p-side guiding layer 161 is decreased stepwise with a decrease in distance from electron blocking layer 62.

Nitride semiconductor light-emitting element 110 that includes p-side guiding layer 161 having Mg concentration distributions as shown in FIG. 11 and FIG. 12 also produces the same advantageous effects as nitride semiconductor light-emitting element 10 according to Embodiment 1.

### Embodiment 7

A nitride semiconductor light-emitting element according to Embodiment 7 will be described. The nitride semiconductor light-emitting element according to the present embodiment is different from nitride semiconductor light-emitting element 10 according to Embodiment 1 in the configuration of a p-side semiconductor layer. Hereinafter, the nitride semiconductor light-emitting element according to the present embodiment will be described, focusing on the differences from nitride semiconductor light-emitting element 10 according to Embodiment 1.

### [7-1. Overall Configuration]

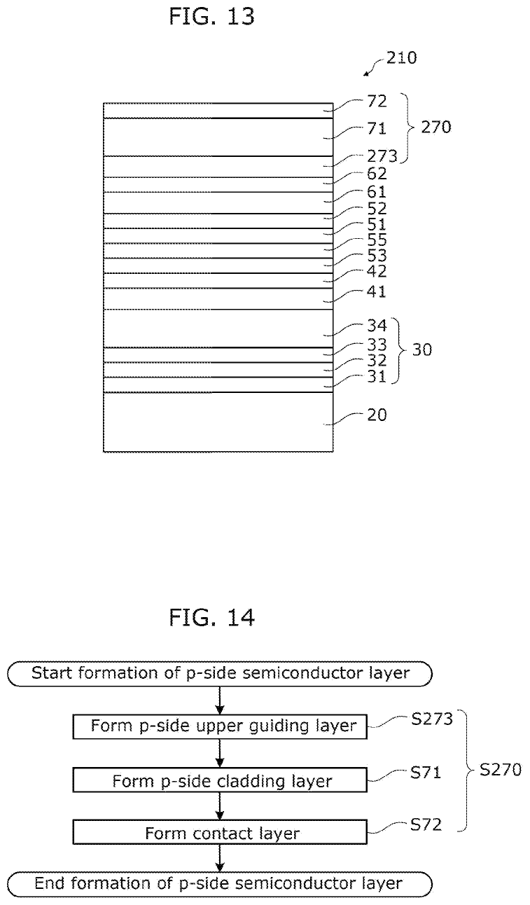

First, the overall configuration of the nitride semiconductor light-emitting element according to the present embodiment will be described with reference to FIG. 13. FIG. 13 is a schematic side view of the overall configuration of nitride semiconductor light emitting element 210 according to the present embodiment.

As illustrated in FIG. 13, nitride semiconductor light-emitting element 210 according to the present embodiment includes substrate 20, n-side semiconductor layer 30, first n-side guiding layer 41, second n-side guiding layer 42, third barrier layer 53, light-emitting layer 55, first barrier layer 51, second barrier layer 52, p-side guiding layer 61, electron blocking layer 62, and p-side semiconductor layer 270.

P-side semiconductor layer 270 according to the present embodiment includes p-side upper guiding layer 273, p-side cladding layer 71, and contact layer 72. P-side upper guiding layer 273 is a nitride semiconductor layer that is disposed above electron blocking layer 62 and has a refractive index higher than the refractive index of p-side cladding layer 71. In the present embodiment, p-side upper guiding layer 273 is a p-type Al_{0.03}Ga_{0.97}N layer having a thickness of 0.06 μm. P-side semiconductor layer 270 including p-side upper guiding layer 273 can improve a light confinement effect of nitride semiconductor light-emitting element 210. Note that the configuration of p-side upper guiding layer 273 is not limited to the above-described configuration. P-side upper guiding layer 273 may be a p-type GaN layer having an Al composition ratio of zero or may be a p-type Al_{0.06}Ga_{0.94}N layer having an Al composition ratio of 6%, for example. In addition, Mg may be intentionally added to p-side upper guiding layer 273 or need not be added to p-side upper guiding layer 273.

### [7-2. Manufacturing Method]

Next, the manufacturing method of manufacturing nitride semiconductor light-emitting element 210 according to the present embodiment will be described with reference to FIG. 14. FIG. 14 is a flowchart illustrating forming processes of forming p-side semiconductor layer 270 in nitride semiconductor light-emitting element 210 according to the present embodiment.

Among processes included in the manufacturing method of manufacturing nitride semiconductor light-emitting element 210 according to the present embodiment, the processes other than forming processes of forming p-side semiconductor layer 270 are the same as respective processes included in the manufacturing method of manufacturing nitride semiconductor light-emitting element 10 according to Embodiment 1. Accordingly, descriptions of the processes other than the forming processes of forming p-side semiconductor layer 270 will be omitted.

In the forming processes of forming p-side semiconductor layer 270 according to the present embodiment (S270), p-side upper guiding layer 273 is formed in the first place (S273). Specifically, the supply amount of TMA supplied during the formation of electron blocking layer 62 is reduced to cause p-side upper guiding layer 273 including p-type Al_{0.03}Ga_{0.97}N and having a thickness of 0.06 μm to grow on electron blocking layer 62.

Then, p-side cladding layer 71 is formed in the same manner as Embodiment 1 (S71). Specifically, the supply amount of TMA is increased to cause p-side cladding layer 71 including p-type Al_{0.08}Ga_{0.92}N and having a thickness of 0.5 μm to grow on p-side upper guiding layer 273.

Then, contact layer 72 is formed in the same manner as Embodiment 1 (S72). Specifically, the supply of TMA is stopped, and the supply amount of Cp₂Mg is increased to cause contact layer 72 including p-type GaN and having a thickness of 10 nm to grow on p-side cladding layer 71.

As has been described above, p-side semiconductor layer 270 according to the present embodiment can be formed.

### Variations, Etc.

Hereinbefore, the nitride semiconductor light-emitting element according to the present disclosure has been described according to the embodiments. However, the present disclosure is not limited to these embodiments.

For example, although the nitride semiconductor light-emitting element according to the above-described embodiments and variations includes base layer 31, strain relaxation layer 32, and capping layer 33, none of these layers are essential elements. The nitride semiconductor light-emitting element according to the present disclosure need not include at least one layer among the above-described layers.

In addition, the nitride semiconductor light-emitting element according to the above-described embodiments and variations may be a semiconductor laser element including a light resonator, may be a light-emitting diode not including a light resonator, and may be a super luminescent diode.

In the above-described embodiments, an n-type GaN substrate is used as substrate 20, but an n-type AlGaN substrate may be used. Since the use of an n-type AlGaN substrate can reduce tensile strain particularly when the Al composition ratio of each of cladding layers including AlGaN is large, the occurrence of defects, such as cracks, in a semiconductor layered body can be prevented. In this case, the Al composition ratio of the n-type AlGaN substrate may be larger than zero and smaller than the Al composition ratio of each of guiding layers including AlGaN. Alternatively, the Al composition ratio of the n-type AlGaN substrate may be between the Al composition ratio of each guiding layer including AlGaN and the Al composition ratio of each cladding layer including AlGaN. When the Al composition ratio of the n-type AlGaN substrate is between the Al composition ratio of each guiding layer including AlGaN and the Al composition ratio of each cladding layer including AlGaN, the Al composition ratio of the n-type AlGaN substrate may be closer to the Al composition ratio of each cladding layer including AlGaN than to the Al composition ratio of each guiding layer including AlGaN. Alternatively, the Al composition ratio of the n-type AlGaN substrate may be larger than the Al composition ratio of n-side cladding layer 34 including n-type AlGaN. When the Al composition ratio of the n-type AlGaN substrate is larger than the Al composition ratio of the n-side cladding layer including n-type AlGaN, leakage of light into substrate 20 can be reduced.

Those skilled in the art will readily appreciate that various modifications may be made in these embodiments and that other embodiments may be obtained by optionally combining the elements and functions of the embodiments without materially departing from the novel teachings and advantages of the present disclosure. Accordingly, all such modifications and other embodiments are included in the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The nitride semiconductor light-emitting element according to the present disclosure can be applicable to, for example, as a high-output, high-efficiency short-wavelength light source, a light source for various uses such as a light source for exposure.

1. A nitride semiconductor light-emitting element comprising:
an n-side semiconductor layer;
one or more light-emitting layers disposed above the n-side semiconductor layer;
a first barrier layer disposed above the one or more light-emitting layers and including Al;
a second barrier layer disposed above the first barrier layer and including Al;
a p-side guiding layer disposed above the second barrier layer and having an Al composition ratio smaller than an Al composition ratio of the second barrier layer;
an electron blocking layer disposed above the p-side guiding layer, including Mg, and having an Al composition ratio larger than the Al composition ratio of the second barrier layer; and
a p-side semiconductor layer disposed above the electron blocking layer.

2. The nitride semiconductor light-emitting element according to claim 1, wherein
the Al composition ratio of the second barrier layer is larger than an Al composition ratio of the first barrier layer.

3. The nitride semiconductor light-emitting element according to claim 1, wherein
the p-side guiding layer includes Mg.

4. The nitride semiconductor light-emitting element according to claim 1, wherein
an average Mg concentration in the p-side guiding layer is lower than an average Mg concentration in the electron blocking layer.

5. The nitride semiconductor light-emitting element according to claim 1, wherein
a Mg concentration in the p-side guiding layer in a vicinity of an interface near the second barrier layer is lower than a Mg concentration in the p-side guiding layer in a vicinity of an interface far from the second barrier layer.

6. The nitride semiconductor light-emitting element according to claim 1, wherein
the second barrier layer has a thickness less than a thickness of the first barrier layer.

7. The nitride semiconductor light-emitting element according to claim 1, wherein
the Al composition ratio of the electron blocking layer is larger than the Al composition ratio of the p-side semiconductor layer.

8. The nitride semiconductor light-emitting element according to claim 1, wherein
the one or more light-emitting layers include In, and
a wavelength of light that the nitride semiconductor light-emitting element emits is less than or equal to 390 nm.

9. The nitride semiconductor light-emitting element according to claim 1 further comprising:
a p-side electrode disposed above the p-side semiconductor layer, wherein
the p-side electrode includes Ag.
